(19) United States
(12) Patent Application Publication
(10) Pub. No.: US 2024/0009810 A1
(43) Pub. Date: Jan. 11, 2024

(54) SPRING HOLDER AND WORKPIECE CARRIER

(71) Applicant: Oerlikon Surface Solutions AG, Pfäffikon, Pfäffikon (CH)

(72) Inventors: Rudolf MEILER, Schiers (CH); Sebastian NAHEN, Grabs (CH); Christoph BOURQUAIN, Sevelen (CH)

(21) Appl. No.: 18/247,182

(22) PCT Filed: Sep. 8, 2021
(86) PCT No.: PCT/EP2021/074648

§ 371 Date: Mar. 29, 2023

(30) Foreign Application Priority Data
Sep. 30, 2020 (DE) 10 2020 125 504.7

(51) Int. Cl. B25B 5/16

(52) U.S. Cl. CPC B25B 5/16

(57) ABSTRACT

A spring holder having an elastically deformable latching arrangement and an elastically deformable clamping arrangement; wherein the spring holder is able to be latchingly coupled to a workpiece carrier via the latching arrangement; and the clamping arrangement has an elastically deformable clamping tab, via which, in a clamping position, a retaining force is able to be exerted on a workpiece via a clamping region when the spring holder is coupled to the workpiece carrier, such that the workpiece is able to be frictionally coupled to the spring holder via a clamping face bearing on the clamping region and thus is able to be removably fixed to the workpiece carrier.

### FIELD OF THE INVENTION

The present invention relates generally to a spring holder. The invention furthermore relates to a workpiece carrier.

### BACKGROUND OF THE INVENTION

Spring holders and workpiece carriers are used to fasten workpieces (hereinafter referred to also as substrates), for example workpieces that can be separated, to, in and/or on a workpiece carrier. Furthermore, spring holders and workpiece carriers are used for example to subject the workpieces they hold to a treatment, for example a surface treatment. Such a treatment can include, for example, coating the workpiece surfaces or individual surface sections of the workpieces. The workpieces can be coated for example by a chemical and/or physical process, e.g. by chemical vapor deposition, plasma-enhanced vapor deposition, physical vapor deposition or a combination of these processes. Other possible treatments in this context are, for example, polishing, painting, sanding, sandblasting, ultrasonic cleaning or similar processes. The coating can and usually will take place in a coating facility.

The spring holders (also called clamping springs in this context) can be used to hold individual workpieces in a predetermined position on a fastening segment or receiving area of a workpiece carrier. Spring holders can therefore be used to attach workpieces to a workpiece carrier.

A workpiece carrier is used to carry one or more workpieces, which are fastened by spring holders. In particular, the workpiece carrier serves to carry one or more workpieces that are are attached to it, in one or more predefined positions.

In order to position the individual workpieces to, in and/or on the respective fastening segments, workpieces are fastened, positioned and/or held by spring holders. After positioning, the workpieces can be removed again from the workpiece carrier. Spring holders and workpiece carriers enable workpiece loading and subsequent unloading of the workpiece carrier.

In this connection, the spring holders are particularly suitable for holding a compact workpiece, for example a cuboid, multifaceted workpiece. However, spring holders can also be designed to receive, hold and/or fasten workpieces with a different basic body shape, for example spherical, cubic, ellipsoidal, pyramidal or similar basic body shapes.

In order to ensure the most uniform possible processing result of the workpiece surfaces, the workpieces can be connected to the workpiece carrier and/or the fastening segments of the workpiece carrier in a non-positive (force-locking) and/or positive (form-fitting) manner via the spring holders. Spring holders are known in the state of the art that are fastened to a workpiece carrier in a materially bonded manner, for example through a welded connection.

To load respectively equip the workpiece carrier, the workpieces are usually arranged and clamped between several spring holders. For this purpose, the spring holders are firmly connected to the workpiece carrier. In particular, a materially bonded connection is created by welding the spring holders to the workpiece carrier. However, the welding prevents the manual detaching of the spring holders from the workpiece carrier. Deformation or breakage of a single spring holder results in a lengthy repair and/or a replacement of the workpiece carrier, resulting in operational time delays and additional costs. In order to prevent damage to the spring holders, all spring holders must also be covered if the workpiece carrier is to be cleaned, for example cleaned by sandblasting. Also, covering the spring holders causes time delays and additional costs. In addition, other cleaning processes, for example ultrasonic cleaning, can result in unintentional micro-weld connections between the spring holder and the workpiece in contact with the spring holder. These micro-welded connections are often difficult to detach manually and lead to damage to the spring holder and/or the surface of the workpiece carrier when the workpiece carrier is unloaded. Sensitive workpieces and the spring holders can be damaged in this process.

The object of the present invention is therefore to provide an improved spring holder and an improved workpiece carrier in which these disadvantages are at least partly reduced.

### SUMMARY OF THE INVENTION

The present invention is based on the finding that a special arrangement of the elements of a spring holder and of a workpiece carrier allows rapid installation or replacement of the spring holder as well as rapid removal of the spring holder from the workpiece carrier. In addition, the inadvertent formation of micro-welds between the spring holder and the workpiece during ultrasonic cleaning is reduced or completely eliminated.

In this way, spring holders according to the invention can very quickly be manually, semi-automatically or fully automatically attached to and/or detached from an inventive workpiece carrier. As a result, time-consuming or difficult manual activities can be largely reduced. In addition, a spring holder according to the invention and also a workpiece carrier according to the invention make it possible to equip the workpiece carrier with spring holders for different workpieces. The spring holder according to the invention is a spring holder having an elastically deformable latching arrangement and an elastically deformable clamping arrangement, wherein the spring holder is capable of being latchingly coupled to a workpiece carrier via the latching arrangement. The clamping arrangement has an elastically deformable clamping tab, via which, in a clamping position, a retaining force can be exerted on a workpiece via a clamping region when the spring holder is coupled to the workpiece carrier, such that the workpiece is able to be frictionally coupled to the spring holder via a clamping face bearing on the clamping region and thus is able to be removably fixed to the workpiece carrier.

“Workpiece carrier” describes a plate-shaped carrier element, for example a chassis, a substrate sheet or a holder, which is designed to hold one or more workpieces.

“Latching arrangement” describes an element of the spring holder which is suitable for causing the spring holder to be locked to the workpiece carrier. The spring holder can be locked to the workpiece carrier in a detachable or non-detachable manner by means of one or more latching arrangements. A latching arrangement can be designed, for example, to create a form-fitting and/or form-fitting connection with the workpiece carrier.

The connection between the latching arrangement of the spring holder and the workpiece carrier is preferably designed in such a way that there is some play, i.e. that relative movements between the components are possible. The play, for example a play within an interval of one tenth of a millimeter to five tenths of a millimeter, enables an elastically movable suspension respectively attachment of the spring holder to the workpiece carrier. If there is a vibration, for example a vibration during a cleaning process (e.g. an ultrasonic cleaning process), an elastically-movably mounted spring holder makes a vibration decoupling possible. In other words, this allows the spring holder to oscillate at a different frequency and amplitude than the workpiece held in the spring holder during a vibration process. This vibration decoupling can reduce or prevent undesired welding, for example micro welding between the spring holder and the workpiece. In addition, a connection subject to play is particularly easy to detach. A connection between the latching arrangement, the spring holder and the workpiece carrier that is subject to play can be released and/or created particularly quickly and inexpensively manually or semi-automatically or automatically.

By means of a non-positive and/or positive connection, in particular a snap connection, of the spring elements with the workpiece carriers, joining elements and processes such as weld seams between the spring holder and the workpiece carrier can be saved and the spring elements can be easily replaced.

“Elastically deformable” describes the property of an element and/or a material to change its shape under the influence of force and to return to its original shape when said force is removed. The spring holder can be fastened to the workpiece carrier particularly quickly and manually by means of an elastically deformable latching arrangement. By means of an elastically deformable clamping tab, the spring holder can be adapted to the shape of the workpiece to be held. For example, the elastically deformable clamping tab and/or the elastically deformable latching arrangement can comprise a material of particularly high elasticity and/or formability, such as an austenitic steel. Such an austenitic steel is, for example, the material 1.4310 (X10CrNi18-8), an austenitic chromium-nickel steel with particularly high formability.

“Clamping arrangement” describes another element of the spring holder, wherein the clamping arrangement is adapted for holding a workpiece in contact with it. A clamping arrangement can, for example, form a non-positive connection with the workpiece arranged on it. Furthermore, for example, a clamping arrangement can also form a frictional and/or positive connection with the workpiece arranged on it.

“Latchingly connectable” describes a detachable or non-detachable connection between two elements that was achieved via latching. For example, the spring holder or an element of the spring holder or a section of the spring holder can have a geometry that is suitable for being brought into a latching position with the workpiece carrier.

“Clamping tab” describes an elastic element of the clamping arrangement which fastens the workpiece arranged on it. A clamping tab is a connecting element respectively a connector between several elements. The clamping tab can be arranged, for example, between the workpiece and the workpiece carrier. The clamping tab can for example also include other elements. The clamping tab serves in particular to absorb and/or transmit forces, for example frictional and/or holding forces.

“Clamping position” describes a position or setting of the spring holder in which the spring holder is coupled to the workpiece carrier in a latching manner. In the clamping position, a workpiece can be fastened between the clamping tabs of the respective spring holders. In other words, in the clamping position, the workpiece carrier can be loaded with one or more workpieces and the workpiece or several workpieces can be fixed by the spring holder(s).

“Clamping region” describes a portion of the clamping tab that contacts the arranged workpiece. Forces are transmitted between the workpiece and the spring holder through the clamping region. For example, the clamping region of the clamping tab makes contact with a clamping face in or on a fastening area of a workpiece. The clamping region can have a clamping strip, for example, which is designed as an edge or a fold. Additionally, or alternatively, the clamping region can have a spherically curved clamping clasp, or a clamping clasp that is concave in shape in a cross-sectional profile. Furthermore, for example, clamping points, for example embossed or applied knobs, can be arranged on the clamping region. Clamping points lead to a selective distribution of holding and/or frictional forces.

“Clamping face” describes a surface of a workpiece, a surface section or a portion of a workpiece surface which is arranged in a fastening area of the workpiece and directly contacts the clamping region of the spring holder in a clamping position. The fastening area of a workpiece can be designed, for example, as a holding tab, a latching tab or a latching tongue of the workpiece and/or designed to form a frictional connection with the clamping region of the spring holder.

“Holding force” describes one or more force or forces required to hold the workpiece, wherein the holding force can for example be a force caused by static friction. One or more holding forces can occur, for example, in the clamping position of the spring holder between the clamping face and the clamping region.

“Frictionally engaged” describes a detachable and resilient connection between two elements, which is achieved by frictional forces in the contact areas of the elements connected to one another. A frictional connection can be brought about, for example, in the clamping position of the spring holder between the clamping face and the clamping region.

There are variants in which the latching arrangement comprises a resilient tab which, passing through a mating opening in the workpiece carrier, can be coupled to the workpiece carrier via a latching tongue which acts as a snap hook.

“Resilient” describes the yielding of the tab under compressive stress, wherein the tab returns to its original shape when the compressive stress is removed. In other words, a resilient tab is a tab that can deform elastically and thus absorb mechanical energy. The resilient tab allows the spring holder to be inserted manually into the workpiece carrier in a particularly simple manner. For example, by manually compressing the resilient tab, the resilient tab can be guided particularly easily through a mating opening in the workpiece carrier. Furthermore, for example, the mating opening can have a dimensioning that is smaller than a dimensioning of the resilient tab in a state that is not stressed by compressive force.

A latching tongue acting as a “snap hook” is, for example, a snap connection or an element of a snap connection. A snap connection can include elements for the detachable or non-detachable, simple form-fitting joining of components or elements. In this context, for example, a part to be joined, for example the latching tongue, deforms elastically and then hooks in a detachable or non-detachable manner.

There are versions in which respectively the clamping arrangement and the latching arrangement are arranged in a folded fashion on a base plate.

The base plate is a flat, plate-shaped element of the spring holder. The base plate can have, for example, a rectangular or rectangular-shaped main body. Furthermore, for example, the clamping arrangement and/or the latching arrangement can be arranged on the edges of the base plate.

“Folded” describes an angled arrangement of the clamping arrangement and/or of the latching arrangement on the base plate. In other words, the clamping arrangement and the base plate form an angle and the latching arrangement and the base plate form a further angle. The spring holder can be produced particularly easily and/or geometrically adapted to a corresponding workpiece carrier by means of a folded clamping arrangement and/or a folded latching arrangement.

There are variants in which the spring holder is formed in one piece. One-piece spring holders are formed from a single spring holder molding. A one-piece spring holder allows the spring holder to be produced in a particularly cheap and/or quick manner, for example by stamping a spring holder blank from sheet metal. In addition, or as an alternative, the preformed spring holder can also be cut out of a corresponding shape, such as sheet metal or thin sheet, by laser cutting.

There are variants in which the base plate is rectangular and a first and a second latching arrangement are formed on opposite edges and the clamping arrangement is formed on an edge connecting the opposite edges. “Rectangular” describes a rectangular or rectangular-shaped main body of the base plate, at the edges of which the first and second latching arrangement and the clamping arrangement can be arranged. A spring holder with at least two latching arrangements can be latched onto a workpiece carrier in a particularly secure manner.

There are variants in which the resilient tab includes a lateral plate and a latching tongue. The lateral plate, for example, can be a plate-shaped element with a rectangular main body which is arranged between the base plate and the latching tongue. The latching tongue can also be, for example, a plate-shaped element with a rectangular main body. The lateral plate and latching tongue can be arranged at an angle to one another. The lateral plate and latching tongue can be designed in one integral piece.

There are embodiments in which a latching end is arranged on a projection formed on the latching tongue. “Latching end” describes an end section of the latching tongue or an end section of a projection formed on the latching tongue. Such a latching end can, for example, have a rectangular or similarly suitable profile which is designed to engage in a latching slot and/or to latch with a latching slot and/or to engage in a latching notch and/or to engage in a force-locking connection and/or a form-fitting connection and/or a contact connection and/or a frictional connection. The latching end can be defined by a thickness of the latching tongue. The latching end can be formed in one piece integrally with the latching tongue and/or be a section of the latching tongue.

Alternatively, the latching end can also be arranged on a projection formed on the latching tongue. A projection describes a shoulder, a protrusion or a latching tab which extends from the latching tongue or an end section of the latching tongue. A projection enables a particularly quick manual, semi-automatic or automatic insertion or removal of the spring holder on the workpiece carrier. In particular, a projection can make it easier to insert the spring holder into the workpiece carrier.

There are variants in which the clamping tab comprises a clamping leg and a guide leg, the clamping leg and the guide leg enclosing a clamping angle, wherein the clamping angle has a magnitude between 60° and 170°, preferably between 115° and 125°. In other words, the clamping angle is formed by the guide leg and the clamping leg. In a clamping position or clamping setting of the spring holder, the clamping angle of the elastic clamping tab can for example be widened further. Furthermore, for example, the clamping angle can also define the dimension and/or shape of the clamping region.

There are variants in which the clamping region comprises a clamping strip, which is designed as an edge and/or a fold, or a clamping clasp, which is designed as a spherically curved tab. An edge respectively a border can be formed for example as a single straight edge or as an edge with recesses. A fold can be formed for example as a step, an edge, a fold or as a groove-shaped transition. In this respect, the fold can be designed as a single fold or as a fold with recesses. Alternatively, the clamping region can have a clamping clasp, which is designed as a spherically curved tab. A spherically curved tab can have a concave, convex or U-shaped cross-sectional profile.

There are variants in which the clamping region has at least one clamping point. A clamping point is, for example, a spherical, cylindrical or punctiform arching or curvature that extends from a surface of the clamping region. For example, a clamping point may extend perpendicularly or angularly from the clamping region. Clamping points are suitable for minimizing a contact area between the spring holder and the workpiece to a particularly great extent, which allows particularly favorable access to exposed workpiece surface sections when the workpieces are being machined. The clamping region can also have several clamping points.

There are variants in which the at least one clamping point is in the form of an embossed or applied nub. A nub can be formed, for example, as a hump-like elevation or knot-like thickening Several clamping points can also for example be formed as embossed and/or applied nubs.

There are variants wherein the latching arrangement and the clamping arrangement extend from the base plate in a first vertical orientation. The first vertical orientation describes one or more directions that extend in an angular interval from a main extension plane. The main extension level is defined by at least one longitudinal and one lateral edge of the base plate. For example, a first vertical orientation can include a first angular interval from 0° to 180°. Furthermore, for example, the lateral plate and the base plate can enclose a lateral angle and the base plate and the clamping leg can enclose a contact angle. Furthermore, for example, the lateral angle and the contact angle can each have an angular magnitude which lies within the first angular interval, so that the position of the lateral plate and the position of the clamping leg lie within the first vertical orientation. The angular magnitude of the lateral angle can be different from or equal to the angular magnitude of the contact angle.

Alternatively, there are variants wherein the latching arrangement and the clamping arrangement extend from the base plate in opposite vertical orientations. For example, the clamping tab may extend from the base plate in a first vertical orientation while the latching arrangement extends in a second vertical orientation. The second vertical orientation can include a second angular interval of 180° to 360°, for example. Furthermore, for example, the contact angle can have an angular magnitude in the second angular interval. In this position, the clamping tab extends in a vertical orientation that is opposite to the vertical orientation of the latching arrangement.

A workpiece carrier according to the invention is a workpiece carrier for holding a plurality of workpieces with a plurality of removable spring holders, of which at least two clamping regions are arranged in such a way that in each case one fastening area of a workpiece is held by the clamping region with a clamping face facing the respective clamping region in the clamping position with elastic deformation of the clamping tab.

“Fastening area of a workpiece” describes an area or portion of a workpiece that includes the clamping face that directly contacts the clamping portion of the spring holder in a clamped position.

“Elastic deformation” describes a reversible change in shape of an element as a result of an external force. For example, the clamping tab or individual sections of the clamping tab, such as the clamping region and/or the guide leg and/or the clamping leg, can be elastically deformable under the action of an external force.

Alternatively, or additionally, however, the workpiece and/or the fastening area and/or the clamping face can also be elastically deformable under the influence of an external force. An elastic deformability of the clamping tab allows for example the formation of a frictional connection between the clamping face of the workpiece and the clamping region of the spring holder. In addition, an elastically deformable clamping tab allows a rigid workpiece to be clamped. In other words, for example, the workpiece and/or the fastening area and/or the clamping face can comprise or be formed from a material that is harder and/or less elastic than the clamping tab and/or the material of the clamping tab. Alternatively, for example, the workpiece and/or the fastening area and/or the clamping face can include or be formed from a material that is softer and/or more elastic than the clamping tab and/or the material of the clamping tab. As a further alternative, an elastic deformability of the workpiece and/or the fastening area and/or the clamping face allowed, for example, a rigid or constant arrangement of the spring holder. A rigid arrangement of the spring holder reduces stress on the spring holder and reduces wear on the spring holders and/or the workpiece carrier.

There are embodiments in which the two clamping regions are arranged facing each other and the fastening area is held between the clamping regions. For example, two mutually facing clamping regions of respective spring holders can be arranged in such a way that they are arranged in mirror symmetry or offset on the workpiece carrier or within an opening slot of the workpiece carrier. In particular, two clamping regions can be arranged in such a way that they fix a fastening area in a clamping position. Alternatively, two clamping regions facing each other can also be arranged in such a way that they fix several fastening areas of a workpiece. In a clamping position of the spring holder, two clamping regions facing one another allow a particularly uniform distribution of the holding forces on the respective clamping faces.

There are embodiments in which the workpiece carrier comprises a plurality of mating openings, wherein a resilient tab of the latching arrangement, passing through the mating opening in the workpiece carrier, can be coupled to the workpiece carrier via a latching tongue which acts as a snap hook; and wherein the dimensions of the mating openings in the workpiece carrier and the dimensions of the resilient tabs are matched to one another such that the spring holder is fixed to the workpiece carrier with at least one degree of freedom of movement transversely to a mating direction in which the resilient tabs pass through the mating opening.

“Mating direction” describes a direction along which the resilient tabs pass through the mating openings. The mating direction can extend parallel to a width direction of the workpiece carrier. A direction transverse to the mating direction runs orthogonally to the mating direction. For example, a direction transverse to the mating direction runs parallel to the longitudinal direction of the workpiece carrier.

“Dimensions of the mating opening” describes the dimensions of the mating opening, such as the longitudinal and/or width edges of the mating opening. “Dimensions of the resilient tab” describes the dimensions of the resilient tab.

“Degree of freedom of movement” describes independent movement possibilities of an element. For example, the spring holder can have at least one degree of freedom of movement transversely to the mating direction. In other words, the spring holder can be displaced along the direction transverse to the mating direction, i.e. a direction parallel to the longitudinal direction of the workpiece carrier, after the spring holder has been inserted into the workpiece carrier. The displacement can be limited by the dimensioning of the mating opening. Alternatively, the displacement can also be made possible by a play. A degree of freedom of movement transverse to a mating direction also allows limited position changes and/or an adjustment of the spring holder in a clamped position in addition to a particularly simple manual use of the spring holder.

There are embodiments in which the resilient tab comprises a lateral plate and a latching tongue, with a latching slot being formed in the area of the mating opening, which accommodates a latching end of the latching tongue, so that the spring holder can be adjusted in the direction of the degree of freedom of movement transversely to the mating direction.

“Area of the mating opening” describes a spatial area that extends around the mating opening, for example a spatial area with an extension interval of preferably 0.5 mm to 2.5 mm.

“Latching slot” describes a rectangular or rectangular-shaped indentation on the workpiece carrier. A latching slot can be designed as a notch, a groove or a recess. The latching slot can form an opening in the workpiece carrier. Alternatively, the latching slot can be designed as a non-continuous recess. A latching slot can be arranged in and/or on the workpiece carrier parallel to a wall of the mating opening, at a distance. The latching slot enables, for example, a connection between the latching tongue and the workpiece carrier that fits precisely or is subject to play. In particular, the spring holder can be arranged on the workpiece carrier so that it can be displaced or adjusted along the latching slot.

There are versions in which the resilient tab comprises a lateral plate and a latching tongue, with a latching notch being arranged on at least one wall of the mating opening, wherein the latching notch receives a latching end of the latching tongue, so that the spring holder can move adjustably in the direction of the degree of freedom of movement transversely to the mating direction.

“Latching notch” describes a groove, cutout or recess formed within a mating opening or on a wall of the mating opening of the workpiece carrier. The latching notch of the mating opening can, for example, have a rectangular or similarly suitable basic shape. The latching notch can enlarge the mating opening. The latching notch can be designed or formed accordingly in order to engage in a force-locking connection and/or a form-fitting connection and/or a contact connection and/or a frictional connection with a latching end of a latching tongue. The latching notch can also be designed to guide and/or fix a latching end. The latching notch allows the latching end to be accommodated, positioned and fixed. For example, a connection between a latching notch and a latching end, which is arranged on a projection, can be designed as a snap connection.

The latching end can run along the latching notch and/or contact the Latching notch. The latching notch can, for example, enable a connection between the latching tongue and the workpiece carrier that is precisely fitting and/or has some play. The latching notch can in particular be designed to receive a latching end of the latching tongue in such a way that the spring holder can be adjusted in the direction of the degree of freedom of movement transversely to the mating direction. With the latching notch, manual, semi-automatic or automatic loading of the spring holder into the workpiece carrier and/or detachment of the spring holder from the workpiece carrier can be carried out particularly quickly.

Further aspects and features of the present invention result from the dependent claims, the accompanying drawing and the following description of the embodiments.

### BRIEF DESCRIPTION OF THE DRAWING

Embodiments of the invention will now be described by way of example and with reference to the accompanying drawing, wherein:

FIG. 1A shows a schematic plan view of an upper side of a workpiece carrier equipped with workpieces and welded-on spring holders according to the state of the art;

FIG. 1B shows a schematic plan view of an underside section of the workpiece carrier shown in FIG. 1A;

FIG. 2A shows a schematic perspective view of an embodiment of a spring holder for fastening a workpiece to a workpiece carrier;

FIG. 2B shows a schematic side view of the spring holder of FIG. 2A;

FIG. 2C shows a schematic plan view of an embodiment of a preformed spring holder according to the invention;

FIG. 2D shows a schematic cross-section along section line A-A shown in FIG. 2C;

FIG. 3A shows a schematic exemplary embodiment of a cross-sectional profile of a clamping arrangement;

FIG. 3B shows another schematic exemplary embodiment of a cross-sectional profile of a clamping arrangement;

FIG. 3C shows another schematic exemplary embodiment of a cross-sectional profile of a clamping arrangement;

FIG. 3D shows another schematic exemplary embodiment of a cross-sectional profile of a clamping arrangement;

FIG. 3E schematically shows a functional principle of embodiments of a workpiece carrier, a workpiece and a spring holder in a clamped position shown in cross-sectional profile;

FIG. 4A shows a schematic plan view of an embodiment of an unloaded workpiece carrier according to the invention;

FIG. 4B schematically shows an enlargement of the area marked with X from FIG. 3A;

5A shows a schematic perspective view of a surface section of a workpiece carrier with two spring holders;

FIG. 5B shows a schematic perspective view of the undersurface section of the workpiece carrier from FIG. 5A;

FIG. 6 shows a schematic perspective view of a further embodiment of a spring holder;

FIG. 7 shows a schematic perspective view of a further embodiment of a spring holder for fastening a workpiece to a workpiece carrier;

FIG. 8 shows a schematic perspective view of a surface section of a workpiece carrier with two spring holders.

### DESCRIPTION OF EMBODIMENTS

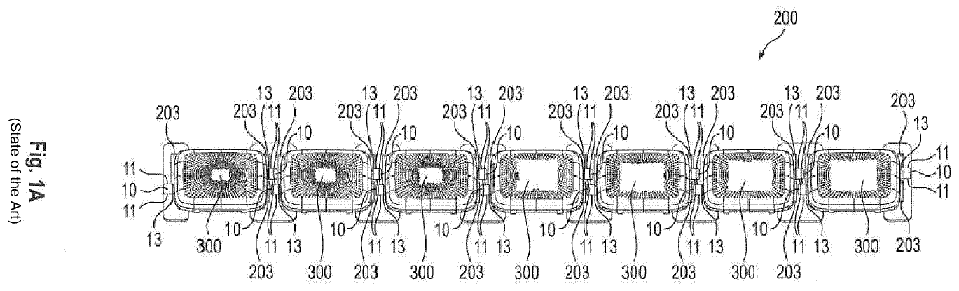

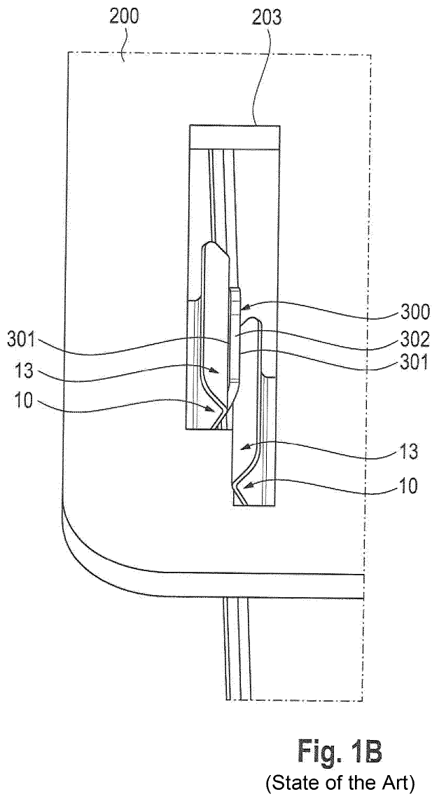

FIG. 1A shows a schematic plan view of an upper side of a workpiece carrier 200 equipped with workpieces 300 and welded-on spring holders 10 according to the state of the art. A plurality of workpieces 300 respectively substrates are arranged on the workpiece carrier 200 at a distance from one another. In addition, several spring holders 10 are arranged on the workpiece carrier 200 respectively substrate sheet. The spring holders 10 are designed to hold the workpieces 300 in place by frictionally engaging the clamping faces of the respective workpiece 300 (not shown). A spring holder 10 according to the state of the art comprises a base plate which is fixed to the workpiece carrier 200 by means of a weld seam 11 in a materially bonded manner at two width edges lying parallel to one another. In addition, the spring holder 10 according to the state of the art includes a clamping arrangement 13. The workpiece carrier 200 comprises a plurality of opening slots 203, within which clamping arrangements 13 of a respective spring holder 10 are arranged. The spring holders 10 are in a clamping position in which the workpieces fixed by them can be processed, cleaned and/or coated.

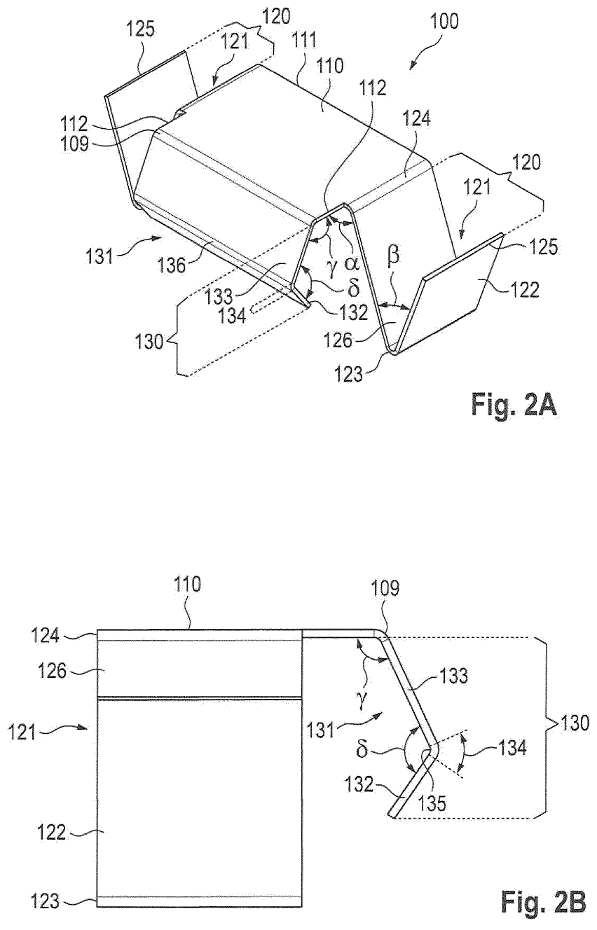

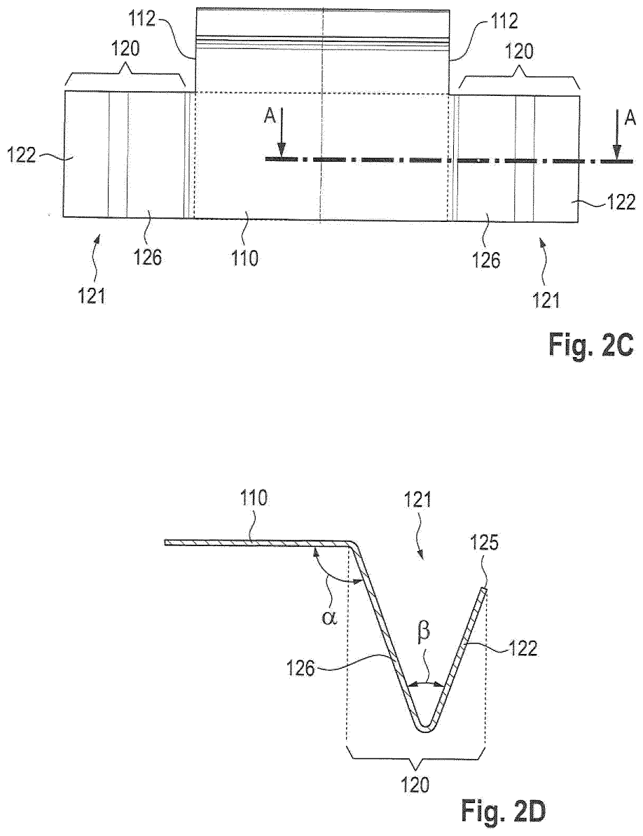

FIG. 1B shows a schematic plan view of an underside section of the workpiece carrier 200 shown in FIG. 1A. Holding tabs respectively fastening areas 302 of the workpiece 300 with a clamping face 301 and a plurality of clamping arrangements 13 of the respective spring holders 10 pass through an opening slot 203 of the workpiece carrier 200. The clamping arrangements 13 each contact a clamping face 301 of the workpiece 300, thereby holding the workpieces 300 in place. FIG. 2A shows a schematic perspective view of an embodiment of a spring holder 100 for fastening a workpiece to a workpiece carrier. The spring device 100 has a base plate 110 with an essentially rectangular or rectangular-like basic shape in a main extension plane, which is defined by longitudinal edges 111 and width edges 112. The spring holder 100 is designed in one integral piece. The spring holder 100 has two elastically deformable latching arrangements 120 and an elastically deformable clamping arrangement 130.

Each of the latching arrangements 120 is folded respectively arranged at an angle on the base plate 110. The spring holder 100 can be made to latch with the workpiece carrier 200 (not shown) via the latching arrangements 120. Each of the latching arrangements 120 has a resilient tab 121 which, passing through a mating opening (not shown) in the workpiece carrier 200, can be coupled to the workpiece carrier via a latching tongue 122 acting as a snap hook. The two latching arrangements 120 are spaced parallel to one another and are each arranged on an edge respectively width edge 112. In other words, a first and a second latching arrangement 120 are formed on opposite edges 112, with the clamping arrangement 130 being formed on an edge 111 connecting the opposite edges. A base fold edge 124 extends between the latching arrangement 120 and the base plate 110. The resilient tab 121 and the base plate 110 enclose a lateral angle α. The lateral angle α can have a magnitude of 100° to 120°, preferably 105° to 115°, most preferably 110°. The lateral angle α defines the base fold edge 124.

The resilient tab 121 comprises a lateral plate 126 and a latching tongue 122. The latching tongue 122 and lateral plate 126 are arranged at an angle to one another. A latching end 125 with a rectangular profile is arranged in an end region of the latching tongue 122. The lateral plate 126 is formed as a plate-shaped element with a rectangular main body. The lateral plate 126 is arranged between the base plate 110 and the latching tongue 122. The lateral plate 126 and the latching tongue 122 are arranged at an angle to one another. The lateral plate 126 and the latching tongue 122 enclose a return angle β. The return angle β can have a magnitude between 30° and 50°, preferably 35° and most preferably 40°. When pressure is applied to a surface of the latching tongue 122, the return angle β can increase or decrease. A lateral fold edge 123 extends between the lateral plate 126 and the latching tongue 122. The return angle β defines the lateral fold edge 123.

The elastically deformable clamping arrangement 130 is arranged on a longitudinal edge 111 of the base plate 110. The clamping arrangement 130 is folded respectively arranged at an angle on the base plate 110. The clamping arrangement 130 has a clamping tab 131. The clamping tab 131 comprises a plate-shaped clamping leg 133, a plate-shaped guide leg 132 and a clamping region 134 which is arranged between the guide leg 132 and the clamping leg 133. The clamping leg 133 and the base plate 110 enclose the contact angle γ. In other words, the clamping leg 133 and the base plate 110 are arranged at an angle to one another. The contact angle γ can be from 105° to 125°, preferably from 110° to 120°, most preferably 115°. The contact angle γ shown in FIG. 2A is 115°. A front fold edge 109 extends between the clamping leg 133 and the base plate 110. The contact angle γ defines the frontal fold edge 109.

The clamping region 134, which has a clamping strip 136, extends between the guide leg 132 and the clamping leg 133. In the clamping position (not shown), the clamping strip 136 contacts the clamping face 301 of a fastening area 302 of a workpiece 300. The clamping leg 133 and the guide leg 132 are arranged at an angle to one another. The clamping leg 133 and the guide leg 132 enclose the clamping angle 8. The clamping angle 8 defines the clamping region 134. The clamping angle δ can have a magnitude of 110° to 130°, preferably 115° to 125°, most preferably 120°. The clamping angle δ shown in FIG. 2A has a magnitude of 120°.

FIG. 2B shows a schematic side view of the spring holder 100 from FIG. 2A. In a clamping position (not shown), the clamping angle δ can expand and the contact angle γ can decrease under the effect of a pressure and/or holding force. As a result, in a clamping position, a holding force can be exerted on a contacting clamping face 301 of the workpiece 300 via the clamping region 134, so that the workpiece 300 can be frictionally coupled to the clamping region 134 via the clamping face 301 resting on the clamping region 134. The guide leg 132 allows a simplified insertion of the spring device 100 into an opening slot 203 of the workpiece carrier 200 (not shown).

FIG. 2C shows a schematic top view of an embodiment of a preformed spring holder 100 according to the invention. The dotted line illustrates the rectangular body shape of the base plate 110.

FIG. 2D shows a schematic cross-section along section line A-A shown in FIG. 2C. In the position of the spring holder 100 shown, the lateral angle α is 110°. In the position of the spring holder 100 shown, the return angle β is 40°.

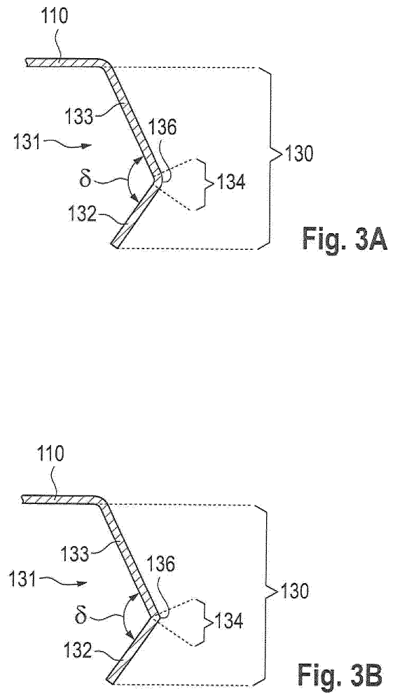

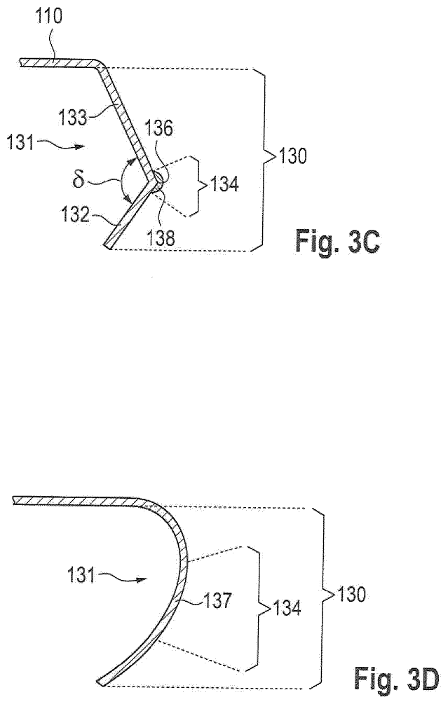

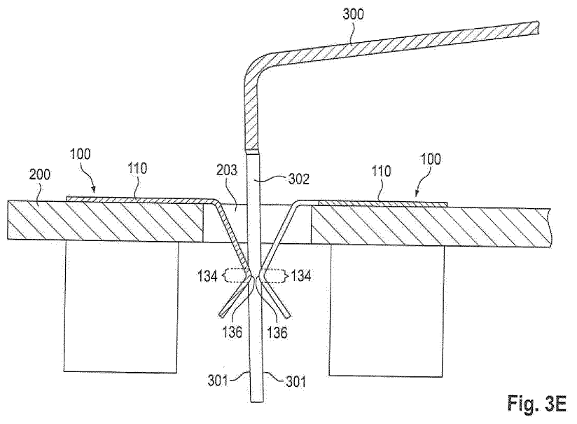

FIGS. 3A, 3B, 3C and 3D each show schematic exemplary embodiments of different cross-sectional profiles of the clamping arrangements 130 with differently shaped clamping tabs 131. FIG. 3A shows a clamping arrangement 130 with a clamping tab 131, which has a clamping region 134 with a clamping strip 136, which is designed as a fold. FIG. 3B shows a clamping region 134 with a clamping strip 136 which is designed as an edge. FIG. 3C shows a clamping region 134 with a clamping strip 136 which is designed as a fold, with a clamping point 138 being arranged on the clamping region 134. The clamping point 138 can be designed as an embossed or applied nub. Nubs can allow particularly non-slip clamping regions 134 to be formed. In FIG. 3C, the clamping point 138 is in the form of an applied nub. FIG. 3D shows a clamping arrangement 130 with a clamping tab 131, which has a clamping clasp 137 in the clamping region 134, which is designed as a spherically curved tab.

FIG. 3E schematically shows a functional principle of embodiments of a workpiece carrier 200, a workpiece 300 and two spring holders 100, shown in cross-sectional profile, in a clamping position. The clamping arrangement 130 passes through the opening slot 203 of the workpiece carrier 200, wherein the clamping strip 136 designed as a fold of the clamping region 134 contacts a facing clamping face 301 of the fastening area 302 of a workpiece 300, whereby the fastening area 302 is fixed and held under elastic deformation of the clamping tab 131.

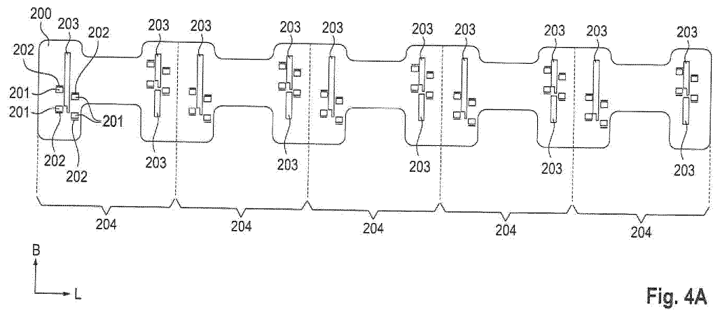

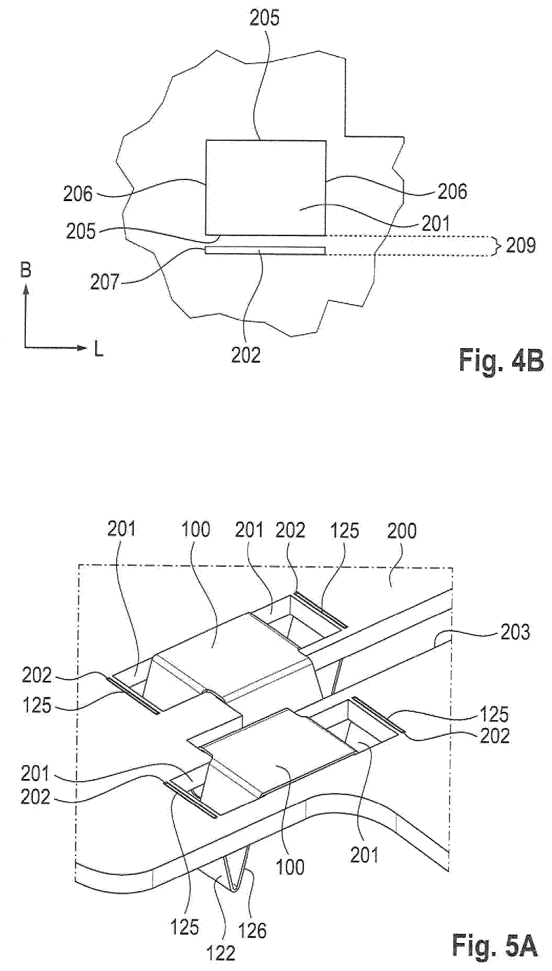

FIG. 4A shows a schematic plan view of an embodiment of an unloaded workpiece carrier 200. The workpiece carrier 200 has five fastening segments 204 arranged parallel next to one another for fastening workpieces 300, with fastening segments 204 arranged next to one another defining a longitudinal direction L of the workpiece carrier. A width direction B of the workpiece carrier is defined by the width of a fastening segment 204. Each fastening segment 204 has three parallel opening slots 203 at a distance from one another, which vary in length and shape from one another. A plurality of pairs of mating openings 201 spaced apart from one another are arranged adjacent to two of the opening slots 203. Each of the mating openings 201 allows a latching arrangement 120 to pass through and serves as a seat for the resilient tab 121 in the clamped position. The resilient tab 121 of the latching arrangement 120 can be coupled to the workpiece carrier 200 by passing through the mating opening 201 in the workpiece carrier 200 via a latching tongue 122 acting as a snap hook. The dimensions of a mating opening 201 in workpiece carrier 200 and the dimension of resilient tab 121 are matched to one another such that the spring holder 100 is fixed to the workpiece carrier 200 with at least one degree of freedom of movement transversely to a mating direction in which the resilient tab 121 passes through the mating opening 201. In other words, the spring holder 100 can be adjusted in a direction parallel to the longitudinal direction L of the workpiece carrier through the existing play.

The mating openings 201 are arranged in such a way that, in a clamping position, two spring devices 100 each have clamping regions 134 which are arranged facing one another. In other words, a single fastening area 302 of a workpiece 300 can be arranged in a clamping position within an opening slot 203 between two facing clamping regions 134 of two spring devices 100 and held on the abutting clamping faces 301 of the two facing clamping regions 134.

FIG. 4B schematically shows an enlargement of the area marked with X from FIG. 3A. The mating opening 201 has a rectangular basic shape, with longitudinal edges 205 of the basic shape extending in a direction parallel to the longitudinal direction L and width edges 206 of the mating opening in a direction parallel to the width direction B. A rectangular latching slot 202 is arranged within an extension interval 209 in the area of the mating opening 201. The width edges 207 of the latching slot are aligned with the width edges 206 of the mating opening. In other words, the width edges 206 of the mating opening and the width edges 207 of the latching slot are aligned in a direction parallel to the width direction B. The latching slot 202 is designed to receive a latching end 125 of the latching tongue 122, so that the spring holder 100 can be adjusted in the direction of a degree of freedom of movement transversely to the mating direction of the spring holder 100.

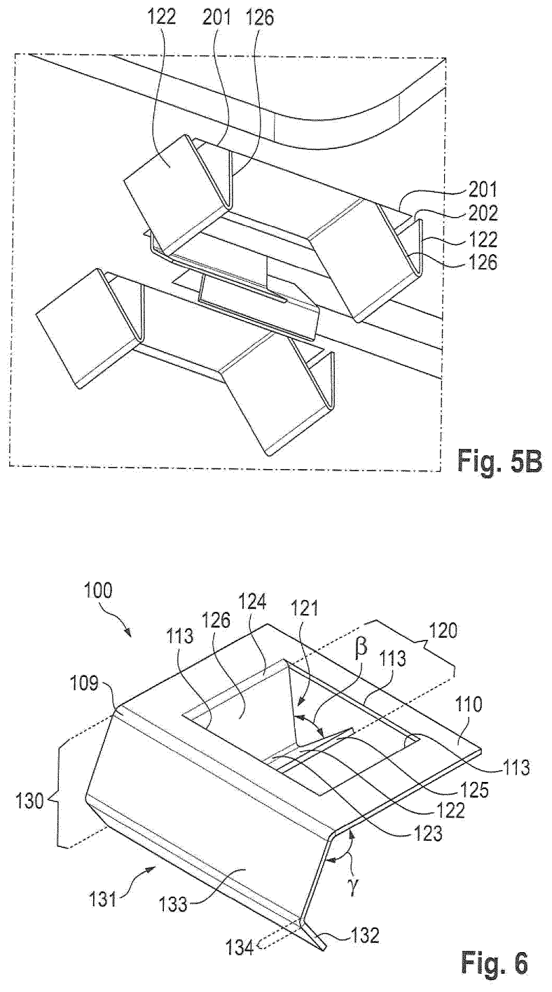

FIG. 5A shows a schematic perspective view of a surface section of a workpiece carrier 200 with two spring holders 100. The spring holders 100 are positioned at two side portions of the opening slot 203 within mating receiving holes 201. The clamping regions 134 of the two spring holders are arranged facing each other (not shown). The latching end 125 of the latching tongue 122 is arranged in a latching manner with the latching slot 202, with the latching end 125 being arranged inside the latching slot 202.

FIG. 5B shows a schematic perspective view of an undersurface section of the workpiece carrier 200 from FIG. 5A. The two spring holders 100 are coupled to the workpiece carrier 200 in a latching manner. The respective clamping portions 134 of the spring holders 100 are arranged facing each other. The respective latching ends 125 of the latching tongues 122 each engage in a latching slot 202 and form a positive and/or non-positive connection.

FIG. 6 shows a schematic perspective view of a further embodiment of the spring holder. The spring holder 100 has a base plate 110 with a basic rectangular shape, on which a clamping arrangement 130 with an elastic clamping tab 131 is arranged. In a clamping position (not shown), a holding force is exerted on a workpiece via the clamping region 134 when the spring holder 100 is coupled to the workpiece carrier. The workpiece (not shown) can be frictionally coupled to the spring holder via the clamping face in contact with the clamping region 134 and can thus be removably fixed to the workpiece carrier (not shown). The spring holder has an elastically deformable latching arrangement 120. The latching arrangement 120 can be coupled in a latching manner to a workpiece carrier. The latching arrangement 120 is formed in one integral piece with the base plate 110. The base plate 110 has three cutting edges 113 connected to one another. The three cutting edges 113 form a U-shaped cut. The latching arrangement 120 is detached from the base plate 110 along the cut and is arranged at an angle to the base plate 110. In other words, the latching arrangement 120 is formed from a portion of the base plate 110. The latching arrangement 120 has a resilient tab 121 which, passing through a mating opening in the workpiece carrier, can be coupled to the workpiece carrier via the latching tongue 122 which acts as a snap hook. The clamping arrangement 130 and the latching arrangement 120 are each arranged folded on the base plate 110. The spring holder 100 is formed in a single integral piece.

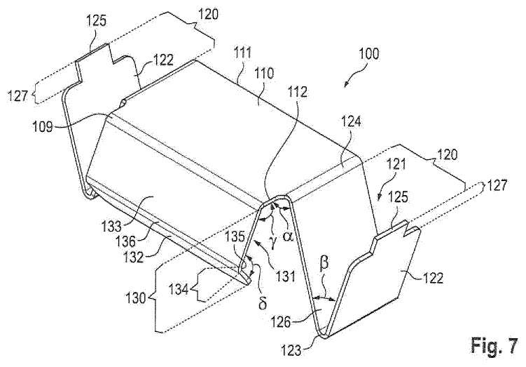

FIG. 7 shows a schematic, perspective illustration of a further embodiment of the spring holder for fastening a workpiece to a workpiece carrier. The spring holder 100 has a latching tongue 122 with a latching end 125, the latching end 125 being arranged on a projection 126 formed on the latching tongue. The latching end 125 is designed as an end section of the projection 126 formed on the latching tongue 122. The latching end 125 has a rectangular cross-sectional profile adapted to engage and/or mate with a latching notch (not shown). The latching end 125, the projection 126 and the latching tongue 122 are integrally formed. The projection 126 extends perpendicularly from an edge of the latching tongue 122.

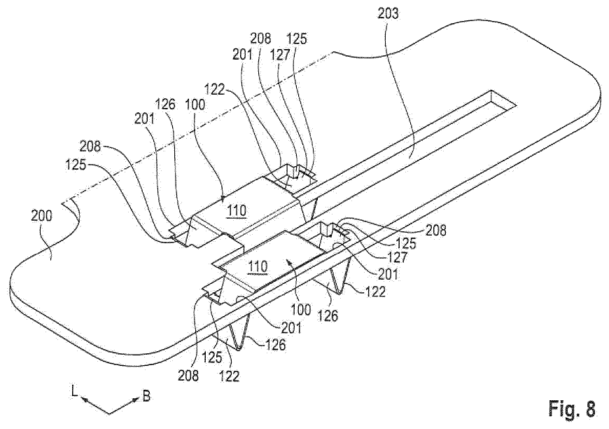

FIG. 8 shows a schematic perspective view of a surface section of a workpiece carrier 200 with two spring holders according to FIG. 7. The mating openings 201 of the workpiece carrier 200 each have a latching notch 208. A latching notch 208 is arranged in each case on a wall of a mating opening 201. A latching notch 208 has a rectangular basic shape. The two spring holders 100 are arranged opposite one another within an opening slot 203 in a clamping position. Each latching notch 208 receives a latching end 125 of a latching tongue 122. Through play (not shown) between the latching end 125 and the latching notch 208, the spring holder 100 can be adjusted in the direction of a degree of freedom of movement transversely to the mating direction. The latching end 125 and the projection 126 run on or within the latching notch 208.

The exemplary embodiments explained above are embodiments of the invention. In the exemplary embodiments, the described components of the embodiments each represent individual features of the invention to be considered independently of one another, which also develop the invention independently of one another and are therefore also to be regarded as part of the invention individually or in a combination other than the one shown. Furthermore, the described embodiments can also be supplemented by further features of the invention that have already been described. Further features and embodiments of the invention will become apparent to those skilled in the art within the scope of the present disclosure and the claims.

### REFERENCE LIST

10 spring holder according to the state of the art
13 clamping arrangement of the spring holder according to the state of the art
100 spring holder
109 front fold edge
110 base plate
111 long edge
112 edge
120 latching arrangement
121 resilient tab
122 latching tongue
123 lateral fold edge
126 lateral plate
130 clamping arrangement
131 clamping tab
132 guide leg
133 clamping leg
134 clamping region
136 clamping strip
138 clamping point
200 workpiece carrier
201 mating opening
203 opening slot
204 fastening segment
300 workpiece
301 clamping face
302 fastening area

What is claimed is:

1. Spring holder (100) having an elastically deformable latching arrangement (120) and an elastically deformable clamping arrangement (130);
wherein the spring holder (100) can be coupled in a latching manner to a workpiece carrier (200) via the latching arrangement (120); and
the clamping arrangement (130) has an elastically deformable clamping tab (131) via which a holding force can be exerted on a workpiece (300) in a clamping position via a clamping region (134) when the spring holder (100) is coupled to the workpiece carrier (200), so that the workpiece (300) can be frictionally coupled to the spring holder (100) via a clamping face (301) in contact with the clamping region (134) and can thus be removably fixed to the workpiece carrier (200).

2. The spring holder (100) of claim 1, wherein the latching arrangement (120) comprises a resilient tab (121) which, passing through a mating opening (201) in the workpiece carrier (200), can be coupled to the workpiece carrier (200) via a latching tongue (122) which acts as a snap hook.

3. Spring holder (100) according to claim 1, wherein the respective clamping arrangement (130) and the latching arrangement (120) are arranged folded on a base plate (110); and wherein the spring holder (100) is integrally formed.

4. Spring holder (100) according to claim 3, wherein the base plate (110) is rectangular and a first and a second latching arrangement (120) are formed on opposite edges (112) and the clamping arrangement (130) is formed on an edge (111) connecting the opposite edges.

5. A spring holder (100) according to claim 2, wherein the resilient tab (121) comprises a lateral plate (126) and a latching tongue (122).

6. A spring holder (100) according to claim 5, wherein a latching end (125) is arranged on a projection (126) formed on the latching tongue (122).

7. Spring holder (100) according to claim 1, wherein the clamping tab (131) comprises a clamping leg (133) and a guide leg (132), wherein the clamping leg (133) and the guide leg (132) enclose a clamping angle (δ), wherein the clamping angle (δ) has a magnitude between 70° and 170°, preferably between 115° and 125°.

8. Spring holder (100) according to claim 1, wherein the clamping region (134) further comprises: a clamping strip (136) which is formed as an edge and/or as a fold; or a clamping clasp (137) which is designed as a spherically curved tab.

9. Spring holder (100) according to claim 8, wherein the clamping region (133) has at least one clamping point (138).

10. Spring holder (100) according to claim 9, wherein the at least one clamping point (138) is in the form of an embossed or applied nub.

11. Workpiece carrier (200) for receiving a plurality of workpieces (300) with a plurality of removable spring holders (100) according to claim 1, of which at least two clamping regions (134) are arranged in such a way that a fastening area (302) of a workpiece (300) is held by the clamping region (134) with a clamping face (301) facing the respective clamping region (134) in a clamping position with elastic deformation of the clamping tab (131).

12. Workpiece carrier (200) according to claim 11, wherein two clamping regions (134) are arranged facing one another, and the fastening area (302) is held between the clamping regions (134).

13. Workpiece carrier (200) according to claim 11, in which the workpiece carrier comprises a plurality of mating openings (201), wherein a resilient tab (121) of the latching arrangement (120), passing through the mating opening (201) in the workpiece carrier (200), can be coupled to the workpiece carrier (200) via a latching tongue (122) which acts as a snap hook; wherein the dimensions (205, 206) of the mating openings (201) in the workpiece carrier (200) and the dimensions of the resilient tabs (121) are matched to one another such that the spring holder (100) is fixed to the workpiece carrier (200) with at least one degree of freedom of movement transversely to a mating direction (B), in which the resilient tabs pass through the mating opening (201).

14. Workpiece carrier (200) according to claim 13, wherein the resilient tab (121) comprises a lateral plate (126) and a latching tongue (122), wherein in the region of the mating opening (201) a latching slot (202) is formed which receives a latching end (125) of the latching tongue (122) so that the spring holder (100) can be adjusted in the direction of the degree of freedom of movement transversely to the mating direction.

15. Workpiece carrier (200) according to claim 13, wherein the resilient tab (121) comprises a lateral plate (126) and a latching tongue (122), wherein a latching notch (208) is arranged on at least one wall of the mating opening (201);
wherein the latching notch (208) receives a latching end (125) of the latching tongue (122), so that the spring holder (100) is adjustable in the direction of the degree of freedom of movement transversely to the mating direction.

16. Spring holder according to claim 7, wherein the clamping angle (δ) has a magnitude between 115° and 125°.
